(19) United States
(12) Patent Application Publication
(10) Pub. No.: US 2023/0305352 A1
(43) Pub. Date: Sep. 28, 2023

(54) ELECTRO-OPTIC DEVICE HAVING SERIAL ELECTRO-OPTIC ELEMENTS

(71) Applicant: Gentex Corporation, Zeeland, MI (US)

(72) Inventors: Mario F. Saenger Nayver, Zeeland, MI (US); Ryan B. Balili, Holland, MI (US); Patrick Kreun, Zeeland, MI (US); Robert R. Turnbull, Holland, MI (US); Donald L. Bareman, Zeeland, MI (US); Winston D. Carston, Grand Rapids, MI (US); Stephen F. Richlich, Holland, MI (US); Leroy J. Kloeppner, Jenison, MI (US)

(73) Assignee: Gentex Corporation, Zeeland, MI (US)

(21) Appl. No.: 18/124,789

(22) Filed: Mar. 22, 2023

Related U.S. Application Data
(60) Provisional application No. 63/322,414, filed on Mar. 22, 2022.

(51) Int. Cl. G02F 1/163; G02F 1/1345; B60R 16/03

(52) U.S. Cl. CPC G02F 1/163; G02F 1/1345; B60R 16/03; G02F 2201/42; E06B 9/24

(57) ABSTRACT

An electro-optic device includes a first electro-optic element and a second electro-optic element in series with the first electro-optic element via a common node conductively connecting the first electro-optic element to the second electro-optic element. A power supply circuitry includes a first node and a second node. The first node connects the power supply circuitry to the first electro-optic element, and the second node connects the power supply circuitry to the second electro-optic element.

### CROSS-REFERENCE TO RELATED APPLICATIONS

This application claims priority under 35 U.S.C. § 119(e) and the benefit of U.S. Provisional Application No. 63/322,414 entitled ELECTRO-OPTIC DEVICE HAVING SERIAL ELECTRO-OPTIC ELEMENTS, filed on Mar. 22, 2022, by Mario F. Saenger Nayver, et al., the entire disclosure of which is incorporated herein by reference.

### TECHNOLOGICAL FIELD

The present disclosure relates generally to electro-optic devices and, more particularly, relates to an electro-optic device having serial electro-optic elements.

### SUMMARY OF THE DISCLOSURE

According to one aspect of the present disclosure, an electro-optic device includes a first electro-optic element. A second electro-optic element is in series with the first electro-optic element via a first shared electrode common to the first electro-optic element and the second electro-optic element. Power supply circuitry includes a first node and a second node. The first node connects the power supply circuitry to the first electro-optic element. The second node connects the power supply circuitry to the second electro-optic element.

These and other features, advantages, and objects of the present device will be further understood and appreciated by those skilled in the art upon studying the following specification, claims, and appended drawings.

### BRIEF DESCRIPTION OF THE DRAWINGS

The invention will now be described with reference to the following drawings, in which:

FIG. 1A is a top plan view of an automobile that incorporates a plurality of electro-optic devices according to one aspect of the present disclosure;

FIG. 1B is a side perspective view of an aircraft that incorporates a plurality of electro-optic devices according to one aspect of the present disclosure;

FIG. 1C is a front perspective view of a building that incorporates a plurality of electro-optic devices according to one aspect of the present disclosure;

FIG. 1D is a fragmentary perspective view of an interior of an aircraft that incorporates a plurality of electro-optic devices according to one aspect of the present disclosure;

FIG. 2 is an exploded perspective view of an electro-optic device according to one aspect of the present disclosure;

FIG. 3 is a side cross-sectional view of an electro-optic device according to one aspect of the present disclosure;

FIG. 4 is an electrical schematic of an electro-optic device according to one aspect of the present disclosure;

FIG. 5 is a side cross-sectional view of an electro-optic device according to one aspect of the present disclosure;

FIG. 6 is an electrical schematic of an electro-optic device according to one aspect of the present disclosure;

FIG. 7 is an electrical schematic of an electro-optic device according to one aspect of the present disclosure;

FIG. 8 is an electrical schematic of an electro-optic device according to one aspect of the present disclosure;

FIG. 9 is an electrical schematic of an electro-optic device according to one aspect of the present disclosure;

FIG. 10 is an electrical schematic of an electro-optic device according to one aspect of the present disclosure;

FIG. 11 is an electrical schematic of an electro-optic device according to one aspect of the present disclosure;

FIG. 12 is an electrical schematic of an electro-optic device according to one aspect of the present disclosure;

FIG. 13 is an exploded perspective view of an electro-optic device according to one aspect of the present disclosure;

FIG. 14 is a side cross-sectional view of an electro-optic device according to one aspect of the present disclosure;

FIG. 15 is an exploded perspective view of an electro-optic device according to one aspect of the present disclosure;

FIG. 16 is an electrical schematic of an electro-optic device according to one aspect of the present disclosure;

FIG. 17 is a plot of electrical potential distribution along a length of an electro-optic element according to one aspect of the present disclosure;

FIG. 18 is an exploded perspective view of an electro-optic device with substrates omitted according to one aspect of the present disclosure;

FIG. 19 is an electrical schematic of an electro-optic device according to one aspect of the present disclosure;

FIG. 20 is a plot of electrical potential distribution along a length of an electro-optic element according to one aspect of the present disclosure; and

FIG. 21 is a side cross-sectional view of an electro-optic device according to one aspect of the present disclosure.

### DETAILED DESCRIPTION OF EMBODIMENTS

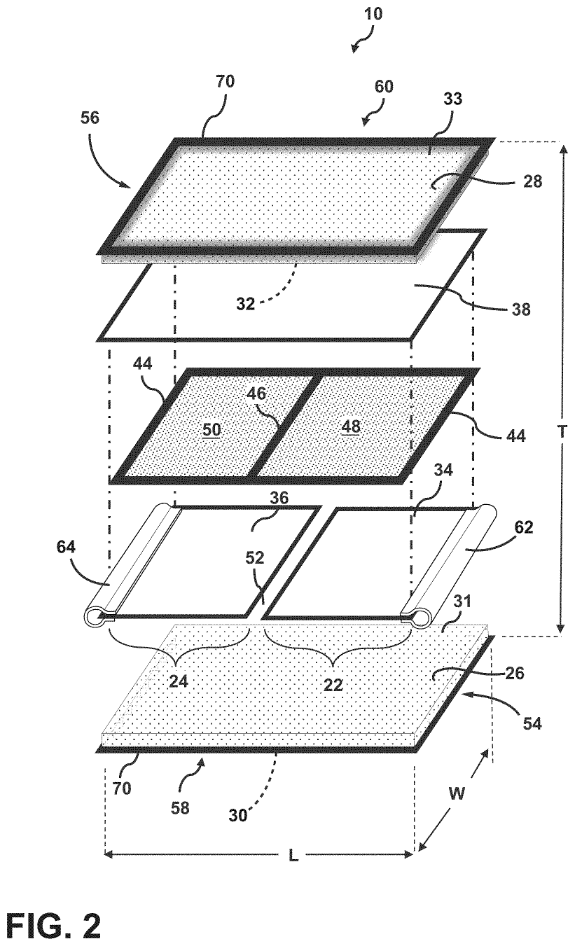

For purposes of description herein, the terms “upper,” “lower,” “right,” “left,” “rear,” “front,” “vertical,” “horizontal,” and derivatives thereof shall relate to the invention as oriented in FIG. 2. However, it is to be understood that the invention may assume various alternative orientations, except where expressly specified to the contrary. It is also to be understood that the specific devices and processes illustrated in the attached drawings, and described in the following specification are simply exemplary embodiments of the inventive concepts defined in the appended claims. Hence, specific dimensions and other physical characteristics relating to the embodiments disclosed herein are not to be considered as limiting, unless the claims expressly state otherwise.

The terms “including,” “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element preceded by “comprises a . . . ” does not, without more constraints, preclude the existence of additional identical elements in the process, method, article, or apparatus that comprises the element.

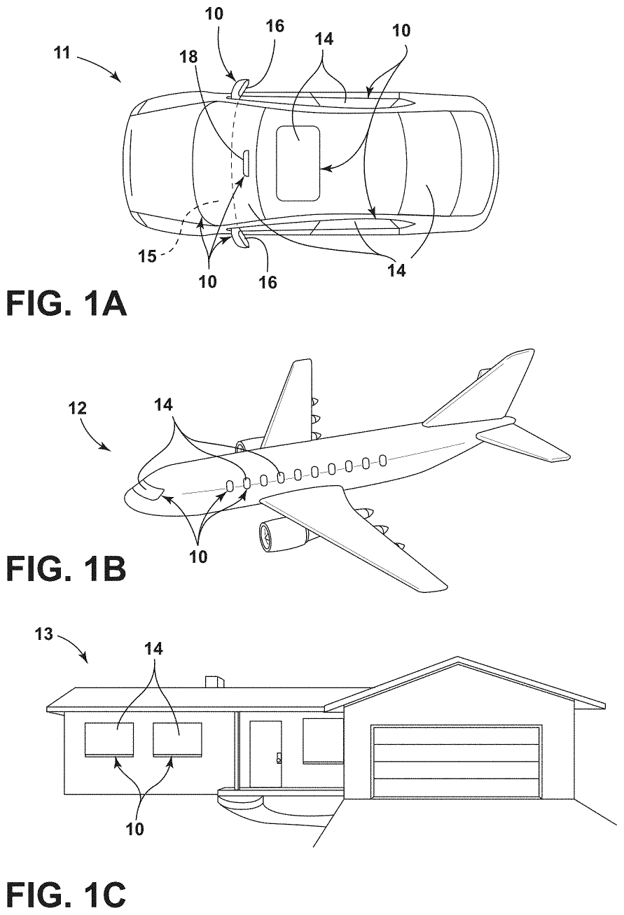

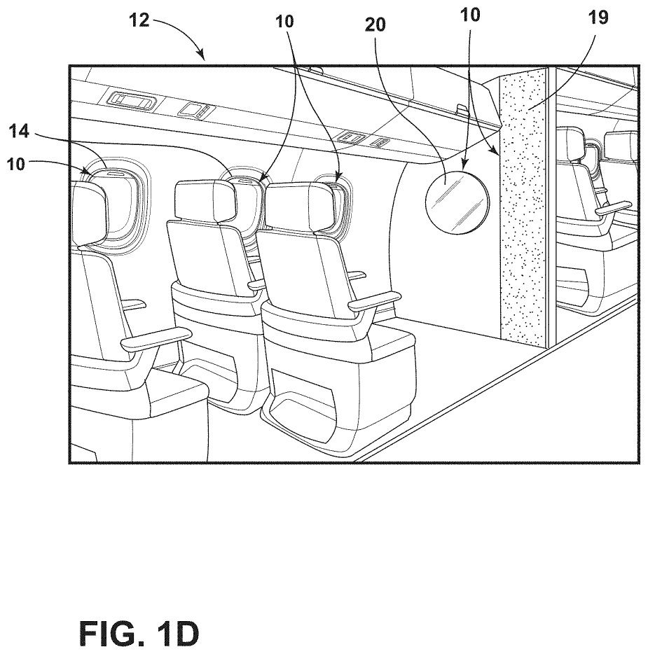

FIGS. 1A-1D illustrate particular embodiments of an electro-optic device 10 incorporated into a structure, such as a vehicle 11, 12, or a building 13. In some embodiments, as shown in FIG. 1A, the vehicle 11, 12 is an automobile 11 that comprises one or more electro-optic devices 10 in the form of a window 14, a dashboard 15, an external rearview mirror 16, and/or an interior rearview mirror 18. The dashboard 15 may be a panel, such as an operator panel, that may be selectively concealable via controlling opacity of the electro-optic device 10. FIG. 1B illustrates another particular embodiment of an electro-optic device 10. In this embodiment, the vehicle 11, 12 is an aircraft 12 that comprises one or more electro-optic devices 10 in the form of the window 14. FIG. 1C illustrates yet another particular embodiment of an electro-optic device 10. In this embodiment, the building 13 may comprise one or more electro-optic devices 10 in the form of the window 14. Though discussed in reference to specific examples, the electro-optic device 10 disclosed herein may be incorporated into various other vehicles, such as recreational vehicles, boats, trailers, trains, spacecraft, gondola lifts, cable cars, etc.

The window 14 may be a device configured to provide a physical barrier between two areas (e.g., an interior and an exterior) and be operable to allow the variable transmission of light between the two areas. The window 14 may come in various configurations. For example, the window 14 may be in the form of a building window, a vehicle windshield, a vehicle side window, a vehicle rear window, a sunroof, a dashboard panel, a divider, mirrors, switchable concealment panels, switchable partitions, and the like.

The external rearview mirror 16 may be a device coupled to an automobile exterior configured to provide a viewer with a field of view comprising an exterior, to the rear or the side, of the automobile 11. Further, interior rearview mirror 18 may also be variably transmissive to minimize glare. The interior rearview mirror 18 may be a device in an automobile interior configured to provide a viewer with a field of view comprising a rearward exterior of automobile 11. Further, the interior rearview mirror 18 may also be variably transmissive to minimize glare.

Referring now to FIG. 1D, an interior of the aircraft 12 is illustrated incorporating the electro-optic device 10 into the window 14, as well as into a partition 19 and a compartment mirror 20. In this example, the window 14 is operable to selectively dim in response to light exposure or the like. Similarly, the compartment mirror 20 may be operable to provide selective or variable levels of transflectance and/or transmittance. The partition 19 may divide the interior into compartments and be controlled to lighten or darken or change opacity.

Referring to the FIGS. 2-4, the electro-optic device 10 includes at least one electro-optic element 22, 24 disposed between a first substrate 26 and a second substrate 28. For example, the at least one electro-optic element 22, 24 may include a first electro-optic element 22 disposed adjacent to a second electro-optic element 24, with each electro-optic element 22, 24 sandwiched or positioned between the first and second substrates 26, 28.

The first substrate 26 has a first surface 30 and a second surface 31 that is opposite the first surface 30. The second substrate 28 has a third surface 32 and a fourth surface 33. The fourth surface 33 is opposite the third surface 32. The second surface 31 faces the third surface 32. Electrodes 34, 36, 38 are disposed adjacent the second surface 31 and/or the third surface 32. In the illustrated example, the at least one electrode 34, 36, 38 includes a first electrode 34 disposed on the second surface 31 of the first substrate 26 and a second electrode 36 disposed on the second surface 31 of the first substrate 26. The at least one electrode 34, 36, 38 also includes a shared electrode 38 disposed on the third surface 32 and spaced from the first electrode 34 and second electrode 36. As will be described in reference to proceeding figures, the arrangement of the three electrodes 34, 36, 38 may be iterative along the first and second substrates 26, 28 to accommodate a plurality of shared electrodes 38 disposed on each substrate 26, 28.

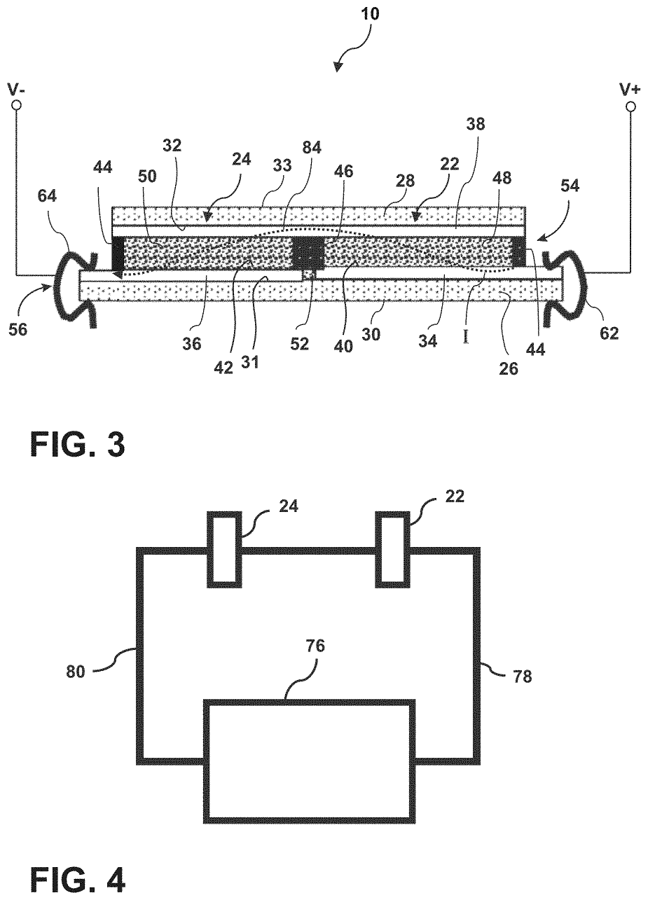

Referring more particularly to FIG. 3, the first electrode 34 and the second electrode 36 may be spaced from the shared electrode 38 to define at least one cavity 40, 42 therebetween. For example, the at least one cavity 40, 42 may include a first cavity 40 disposed between the first electrode 34 and the shared electrode 38. The at least one cavity 40, 42 may also include a second cavity 42 disposed between the second electrode 36 and the shared electrode 38. The first cavity 40 and the second cavity 42 may be electrically isolated from one another by at least one barrier 44, 46 disposed between the first electrode 34 and the second electrode 36. The at least one barrier 44, 46 may also extend from the intermediate electrode 38 to each of the first and second electrodes 34, 36. The at least one barrier 44, 46 may include end barriers 44 and an intermediate barrier 46, with the intermediate barrier 46 separating the first cavity 40 from the second cavity 42. Intermediate barriers, such as 46, are be positioned such that electrodes 34 and 36 are not in contact through the same fluid.

An electro-optic fluid or medium may be disposed in each of the first cavity 40 and the second cavity 42. For example, a first electro-optic segment 48 is formed by the first cavity 40 and a second electro-optic segment 50 is formed by the second cavity 42. The electro-optic fluid may be electrochromic fluid comprising one or more solvents, anodic materials, and/or cathodic materials. In such cases, the anodic and cathodic materials may be electroactive. For example, the first electro-optic segment 48 and the second electro-optic segment 50 may include an electrochromic medium or substance that may alter in color or transmittance when an electrical potential is applied across each of the segments 48, 50. The intermediate barrier 46 between the first cavity 40 and the second cavity 42 may serve to electrically isolate the first electro-optic segment 48 from the second electro-optic segment 50. The intermediate barrier 46 may also serve to physically isolate the first electro-optic segment 48 and the second electro-optic segment 50 and provide structural stability to the electro-optic device 10. The plurality of barriers 44, 46 may be formed of an epoxy resin and may be electrically nonconductive. Further, at least one of the electrodes 34, 36, 38 may include a substantially transparent material that is electrically conductive, such as indium tin oxide (ITO) or another transparent, conductive oxide. The at least one electrode 34, 36, 38 may be surface mounted to the inner surfaces of the first and second substrates 26, 28. It is generally contemplated that any form of ITO or another transparent, electrically conductive material may be employed.

As illustrated in FIGS. 2 and 3, the first electrode 34 may be spaced from the second electrode 36 to define a gap 52 therebetween. The gap 52 may serve to electrically isolate the first electrode 34 from the second electrode 36 and may correspond to the location of the intermediate barrier 46. It is generally contemplated that the first electro-optic element 22 may be formed from the first electrode 34, the first electro-optic segment 48, and the shared electrode 38 and that the second electro-optic element 24 may be formed between the shared electrode 38, the second electro-optic segment 50, and the second electrode 36. The term electro-optic element may be used herein to primarily refer to an electrical characterization of the physical structure illustrated and is not intended to be limited to any specific portion of the at least one electrode 34, 36, 38 or the electro-optic segment 48, 50. It is further contemplated that one or more of the electro-optic elements 22, 24 may include an electrochromic cell.

With continued reference to FIGS. 2 and 3, it is generally contemplated that the electro-optic device 10 may extend between a first end 54 and a second end 56, opposite the first end 54. The electro-optic elements 22, 24 may also be formed in a linear array along a length L of the electro-optic device 10. More specifically, the electro-optic elements 22, 24 may be distributed along the length L, one after the next. With reference to FIG. 2 more particularly, the electro-optic device 10 can include edges 58, 60 that extend between the first end 54 and the second end 56 to form a generally planar shape of the electro-optic device 10. As shown, a first bus 62 may be disposed at the first end 54 of the electro-optic device 10, and a second bus 64 may be disposed at the second end 56 of the electro-optic device 10. The first bus 62 may provide a first power connection to the first electrode 34, and the second bus 64 may provide a second power connection to the second electrode 36. It is generally contemplated that the first end 54 and the second end 56, as well as the busses 62, 64, may be concealed along a top portion or a bottom portion of the electro-optic device 10 via an opaque strip 70 outlining at least a portion of the perimeter of the electro-optic device 10. For example, if the electro-optic device 10 is implemented in a sunroof window, then the busses 62, 64 may be hidden within the perimeter of the sunroof window. The busses 62, 64 may couple to the at least one electrode 34, 36 adjacent the perimeter and also be concealed via the strip 70.

Still referring to FIGS. 2 and 3, the first electro-optic element 22 may be in series with the second electro-optic element 24 via the shared electrode 38. More specifically, the shared electrode 38 may be common to the first electro-optic element 22 and the second electro-optic element 24. In some cases, the common or shared electrode 38 may be separated into one or more segments or sections and conductively connected to form a common node (e.g., with common electrical characteristics or a common voltage). Power supply circuitry 76 may connect to the first electrode 34 and the second electrode 36 adjacent to the corresponding ends of the substrates 26, 28. The power supply circuitry 76 includes a first node 78 and a second node 80, with the first node 78 connecting the power supply circuitry 76 to the first electro-optic element 22 and the second node 80 connecting the power supply circuitry 76 to the second electro-optic element 24. The power supply circuitry 76 may have a relative positive voltage V₊ corresponding with a positive terminal of the power supply circuitry 76 and a relative negative voltage V₋ corresponding with a negative terminal of the power supply circuitry 76. The power supply circuitry 76 may be configured to apply an electrical potential across the first node 78 and the second node 80.

The power supply circuitry 76 may include an alternating current power supply, a variable power supply, a direct current power supply, and/or voltage inverting circuitry for inverting (i.e., making a positive charge negative and vice versa) an electrical potential. According to one aspect of the disclosure, when an electrical potential is applied to the electro-optic device 10 (e.g., across the first electrode 34 and the second electrode 36) an electrical current is configured to flow along an electrical current path 84 (see FIG. 3) through the medium forming the first electro-optic segment 48 and the second electro-optic segment 50 via the shared electrode 38. More particularly, in one aspect of the disclosure, the electrical current path 84 may extend from the first electrode 34, through the first electro-optic segment 48 to the shared electrode 38, then from the shared electrode 38, through the second electro-optic segment 50, to the second electrode 36. The electrical current path 84 may form a plurality of shapes depending on various aspects of the electro-optic device 10. For example, light and/or heat transferred to the electro-optic elements 22, 24 may cause current density to shift in various directions. Further, one or more parts of the electrical current path 84 may deviate from the illustrated path under normal operating conditions. It is generally contemplated that the electro-optic device 10 may be configured to direct current to opposing or adjacent sides of the electro-optic device 10 and that the illustrated configuration is not limiting.

The electrical current path 84 shown in FIG. 3 and described herein may be inverted such that the electrical current may be operable to flow from the second electro-optic element 24 to the first electro-optic element 22, for example, in a symmetrical path illustrated in FIG. 2. It is generally contemplated that the electrical current path 84 illustrated may also have a width profile distributed across a width W of the electro-optic device 10 (FIG. 2). The width profile may be similar or different to the electrical current path 84 illustrated. Furthermore, the path 84 may vary along a length L of the electro-optic device 10. For example, the electrical current path 84 may flow in a sinusoidal-like shape between the first electrode 34 and the second electrode 36. This electrical current path 84 is intended to be exemplary and non-limiting. For example, electrical current can flow from any portion of the first electrode 34 across the first electro-optic segment 48 to the shared electrode 38 along any point of the first electro-optic element 22. The electrical current path 84 shown may illustrate a current density profile through which at least a significant portion of electrical current will flow through. The geometry of the electro-optic elements 22, 24 may impact the specific electrical current path 84 and the path of highest electrical current density. For example, increasing spacing between the elements 22, 24 and/or spacing between the substrates 26, 28 may result in a decreased amplitude of the curve/path 84. In some examples, an electro-optic device 10 having an elongated shape may result in a lengthened path 84 of the electrical current.

When electrical current flows through the electro-optic device 10, each electro-optic segment 48, 50 may be configured to adjust or reduce transmissivity of light through the electro-optic device 10. Continuing with this example, when an electrical potential is removed from between the first electrode 34 and the second electrode 36, thereby limiting electrical current from flowing through the electro-optic device 10, the electro-optic segment 48, 50 may be configured to increase transmissivity of light through the electro-optic device 10. When the electrical potential is reversed, an inverse current may flow between the first and second electro-optic elements 22, 24 to interact with the electro-optic segments 48, 50 to clear or darken the electro-optic element 22, 24. In this way, the power supply circuitry 76 may be configured to control the transmissivity of light through electro-optic device 10 to provide a controlled, dimmable, electro-optic device 10. If an electro-optic element 22, 24 has been previously powered/darkened, the equipotential voltage of the corresponding electrodes may act as a short to clear the electro-optic element 22, 24. Further, reducing the voltage across the electro-optic element 22, 24 below an electrochromic activation threshold, for example, or reverse biasing followed by a float may also clear the electro-optic element 22, 24.

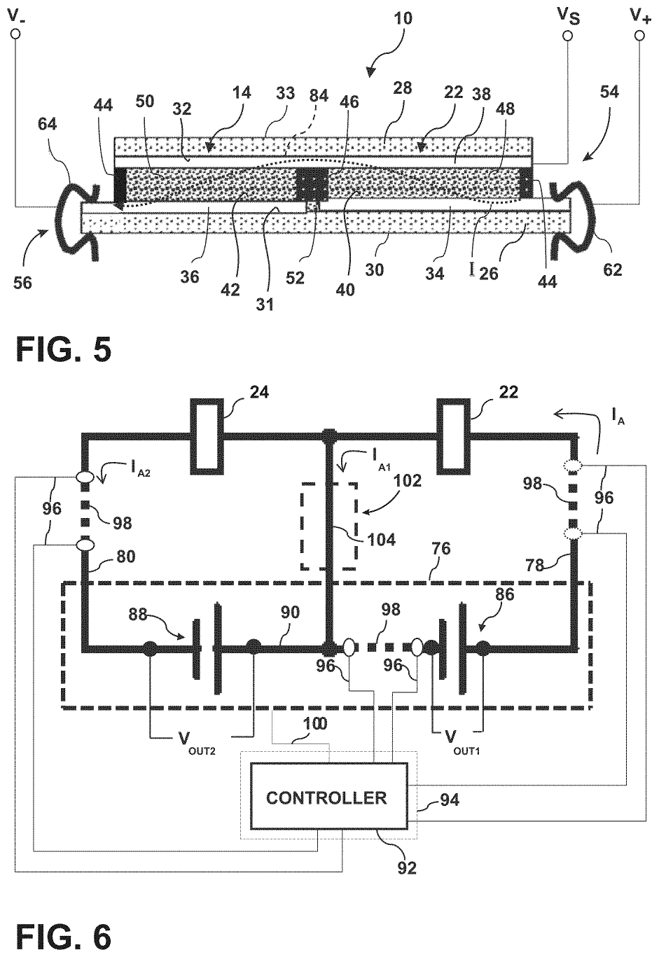

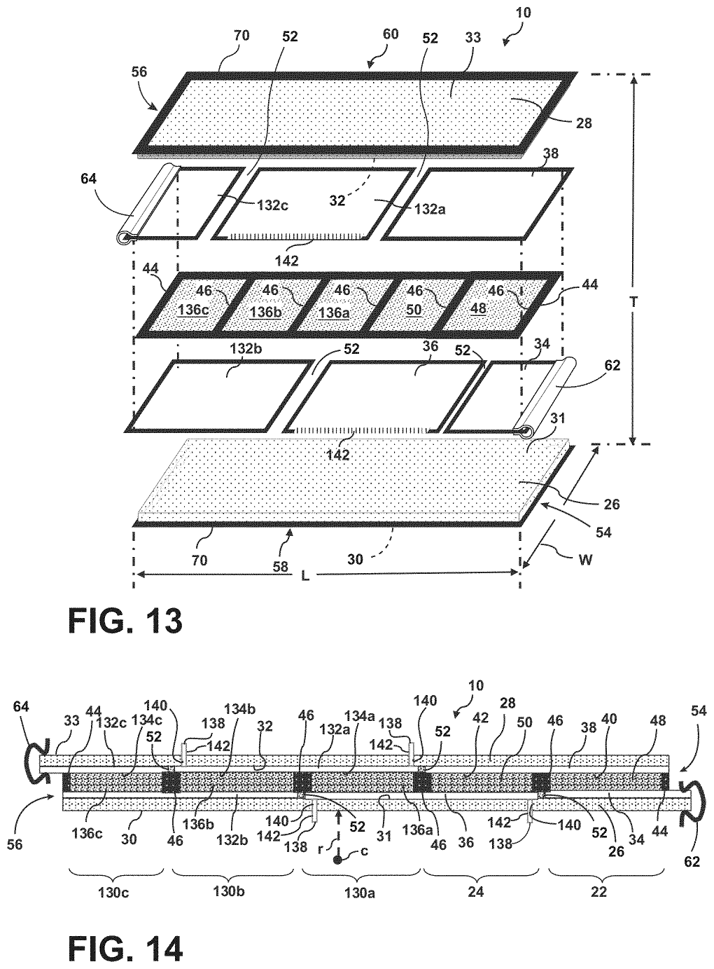

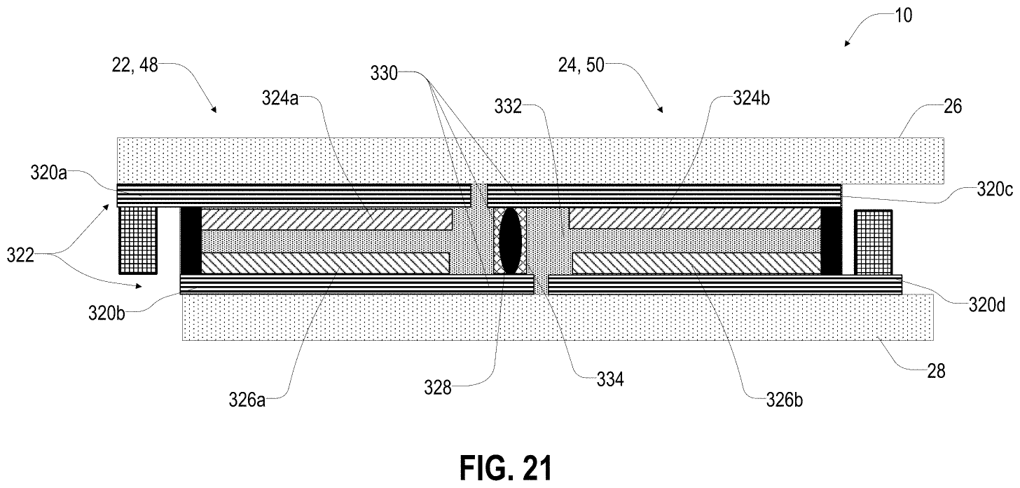

Referring now to FIGS. 5-7, the power supply circuitry 76 may include a first power supply 86 and a second power supply 88. The second power supply 88 may be in series with the first power supply 86 via a third node 90. The third node 90 may connect to the shared electrode 38. As illustrated in FIG. 5, it is generally contemplated that the third node 90 may have access to the shared electrode 38 near one end of either the first substrate 26 or the second substrate 28 and be operable to provide a shared electrode voltage Vₛ associated with the shared electrode 38. Alternatively, the third node 90 may connect to the shared electrode 38 in another manner as later described and illustrated in reference to FIG. 13. As previously described, the shared electrode 38 may be segmented or divided into non-continuous electrode portions in some cases and conductively interconnected to form a common node. An example of such a configuration is shown and discussed in reference to FIG. 21. Accordingly, the shared electrode 38 may correspond to a common node share between or among two or more of the electro-optic elements (e.g., 22, 24) as discussed herein.

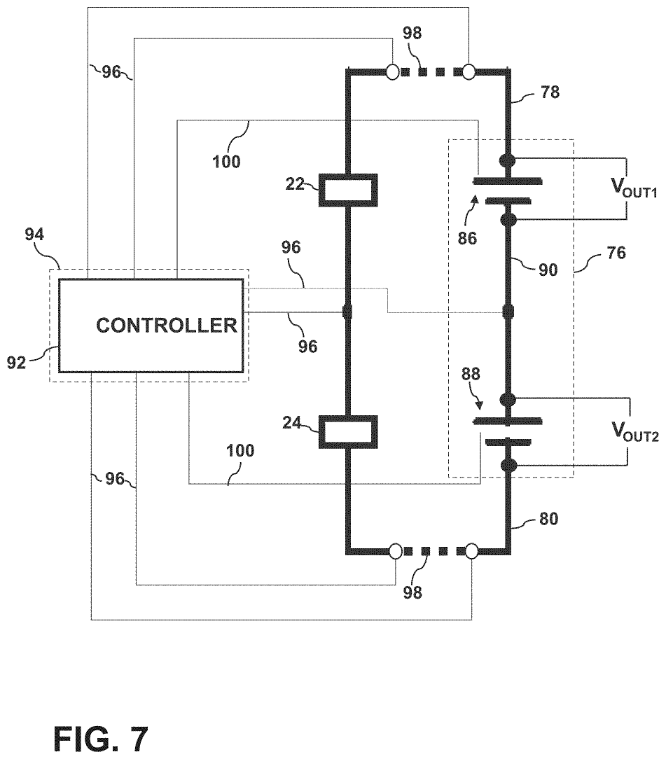

Referring more particularly to FIGS. 6 and 7, a controller 92 may be in communication with one or both of the first power supply 86 and the second power supply 88 and may be operable to control the first power supply 86 and second power supply 88. For example, the controller 92 may be operable to adjust a first output voltage V_{OUT1} of the first power supply 86 and/or a second output voltage V_{OUT2} of the second power supply 88. The controller 92 may also be in communication with any one of the first node 78, the second node 80, and the third node 90 in order to monitor electrical properties of the electro-optic device 10.

By way of example, the controller 92 may be operable to monitor an electrical potential of the third node 90 relative to one or both of the first node 78 and the second node 80. In this way, the controller 92 may further be operable to control one of the first power supply 86 and the second power supply 88 based on the electrical potential associated with the third node 90. Additionally, or alternatively, the controller 92 may be configured to monitor a first current I_{A} flowing through the electro-optic elements 22, 24, including current I_{A1} flowing between the first electro-optic element 22 and the third node 90. The controller 92 may be operable to control one or more of the first power supply 86 and the second power supply 88 based on any one of currents I_{A}, I_{A1}, 1_{A2}. The current I_{A} through the first electro-optic element 22 may equal a sum of the current I_{A2} flowing through the second electro-optic element 24 and the current I_{A1} flowing between the shared electrode 38 and the third node 90. It is generally contemplated that, although the power supply circuitry 76 as exemplarily shown comprises first and second DC power supplies, any type of power supply may be employed to achieve the electrical properties of the electro-optic device 10 (e.g., at least one AC power supply, bridge rectifiers, voltage inverter circuitry, etc.).

According to some aspects of the disclosure, the third node 90 may not have a direct electrical connection with the shared electrode 38 (see FIG. 7). According to some aspects of the present disclosure, the controller 92 may be electrically connected via control circuitry 94 to the shared electrode 38, as well as be electrically connected via the control circuitry 94 to the first node 78 and the second node 80. The controller 92 may be operable to control the power supply 86, 88 based on electrical potential between the shared electrode 38 and either or both of the first node 78 and the third node 90. For example, the control circuitry 94 may include control circuit nodes 96 electrically connecting with the first, second, and/or third nodes 78, 80, 90 to monitor voltages associated with the nodes 78, 80, 90. Additionally, or alternatively, the control circuit nodes 96 may be configured to monitor current passing through one or more of the first, second, or third nodes 78, 80, 90. For example, any one of the first, second, and third nodes 78, 80, 90 may include an open portion 98 to allow control circuit nodes 96 to complete the electrical circuit. It should be appreciated that other current-monitoring techniques may be employed to monitor the current flowing through the first, second, and/or third nodes 78, 80, 90. The control circuitry 94 may further include communication nodes 100 operable to control and/or monitor the power supply circuitry 76. The communication nodes 100 may have voltages or currents that operate to change the voltage of the one or more power supplies, such as power supplies 86, 88.

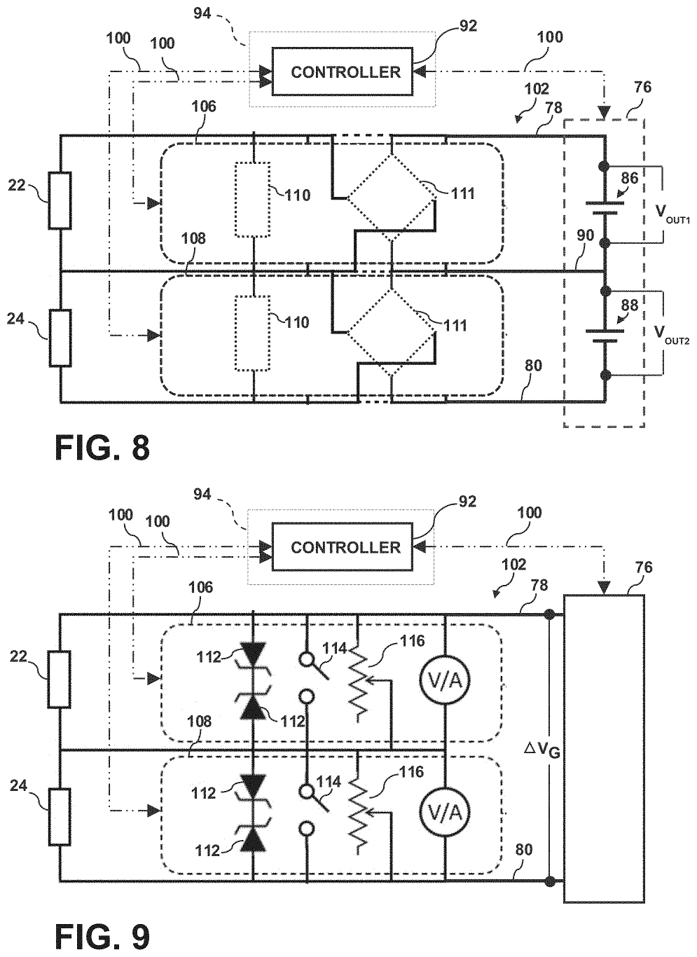

The electro-optic device 10 may also include power regulation circuitry 102 interposed between the shared electrode 38 and one or both of the first node 78 and the second node 80. With specific reference to FIG. 6, the power regulation circuitry 102 may include an electrical short 104 between the third node 90 and the shared electrode 38. In this manner, current may be regulated through the electro-optic element 22, 24 (e.g., current I_{A} may be diverted from current I_{A2}). Other arrangements of the power regulation circuitry 102 are described later with respect to FIGS. 8-12, 16, and 19.

Referring now to FIGS. 8-11, the power regulation circuitry 102 may include a first power regulation circuit 106 and a second power regulation circuit 108. The first power regulation circuit 106 may electrically interpose the first node 78 and the third node 90. The second power regulation circuit 108 may electrically interpose the second node 80 and the third node 90. Further, the first power regulation circuit 106 may be electrically in parallel with the first power supply 86, and the second power regulation circuitry 108 may be electrically in parallel with the second power supply 88, as illustrated in FIG. 8. One or more of the first power regulation circuitry 106 and the second power regulation circuitry 108 may include at least one of a resistor 110, an H-bridge 111 (e.g., a 4-transistor circuit for inverting polarity), a diode (including, e.g., shunt regulator circuitry 112), a switch 114, a variable resistance device 116, and any other type of power regulation circuitry 102. The switch 114 may be in the form of a transistor such as a MOSFET or a BJT transistor configured to operate as the switch 114 to allow electrical current to flow through the switch 114. It is generally contemplated that the shunt regulator circuitry 112 may include a pair of Zener diodes symmetrically opposing one another for bipolar operation, with breakdown voltages tuned at a critical voltage (e.g., 1.2 V accounting for a forward voltage of one or both Zener diodes) of the electro-optic elements 22, 24. As exemplarily shown, the controller 92 may be in electrical communication with the power regulation circuitry 102 and operable to control at least a portion of the power regulation circuitry 102. For example, a voltage or a current provided via the control circuitry 94 may be operable to alter a resistance, a capacitance, an inductance, a voltage, or a current of the power regulation circuitry 102.

The power regulation circuitry 102 may serve to regulate voltage and/or current flowing through the first electro-optic element 22 and the second electro-optic element 24. More particularly, the first power regulation circuit 106 may serve to regulate a voltage of approximately 1.2 V or less across the first electro-optic element 22. The second power regulation circuit 108 may be operable to maintain a similar voltage across the second electro-optic element 24. In this way, overvoltage across the electro-optic elements 22, 24 may be limited, thereby limiting damage to one or more electrical components of the electro-optic device 10. Further, the power regulation circuitry 102 may allow the first electro-optic element 22 to be in electrical series with the second electro-optic element 24 without the second electro-optic element 24 experiencing excess current or overvoltage. For example, the power regulation circuitry 102 can include current-sinking and voltage-regulation devices, such as resistors, diodes, integrated circuits (ICs), and/or other analog or digital circuit elements.

Referring more specifically to FIGS. 9-11, the power supply circuitry 76 may be configured to provide a global voltage V_{G} to the electro-optic device 10 (via, e.g., a single power supply). In the exemplary illustrations shown, the power regulation circuitry 102 includes active electrical components including individual power supply circuits. For example, voltage regulation can be achieved by using a combination of diodes, resistors, potentiometers, rheostats, capacitors, transistors, and integrated circuits (e.g., LM317), and switching can be achieved via a combination of diodes, transistors, relays, gates, resistors, and ICs. Voltage regulation and switching can be combined with the power regulation circuitry 102 and/or in parallel with each electro-optic element 22, 24 to regulate and/or supply voltage to the electro-optic elements 22, 24. The parallel arrangement of the power regulation circuitry 102 with the electro-optic elements 22, 24 may serve to maximize full powering potential (e.g., 0.8-1.2 V), to modulate the voltage, and/or to bypass one or more electro-optic elements 22, 24 by shorting the electrodes or putting the electrodes of that electro-optic element at equipotential.

Referring to FIG. 9 more specifically, the voltage regulation circuitry 102 and switching may be coordinated through a controller or logic device and a single variable power supply that sets the global voltage V_{G} so that the voltage across the device 10 (e.g., all electro-optic elements of the device 10) may be limited by the sum of the desired powering voltages of each electro-optic element 22, 24 to avoid over-voltage. According to various aspects of the present disclosure, voltage/current sense circuits may be included to coordinate with a single power source so that the electro-optic elements 22, 24 may not be subject to over-voltage. Coordination may be managed by a microcontroller configured and/or programmed to control the voltages. For example, the individual power supply circuits may step down the global voltage V_{G} to localized voltages for the individual electro-optic elements 22, 24. For example, in the case of two electro-optic elements 22, 24, the power supply circuitry 76 may be operable to provide approximately 2.4 V globally, and the individual power regulation circuits 106, 108 may be operable to regulate the 2.4 V to provide a localized voltage of 1.2 V to each electro-optic element 22, 24. It will be appreciated that similar functional characteristics may be obtained by employing multiple individual power supplies. The voltages described herein are intended for exemplary purposes, and the electro-optic device 10 of the present disclosure is not required to operate under these specific voltage values or ranges.

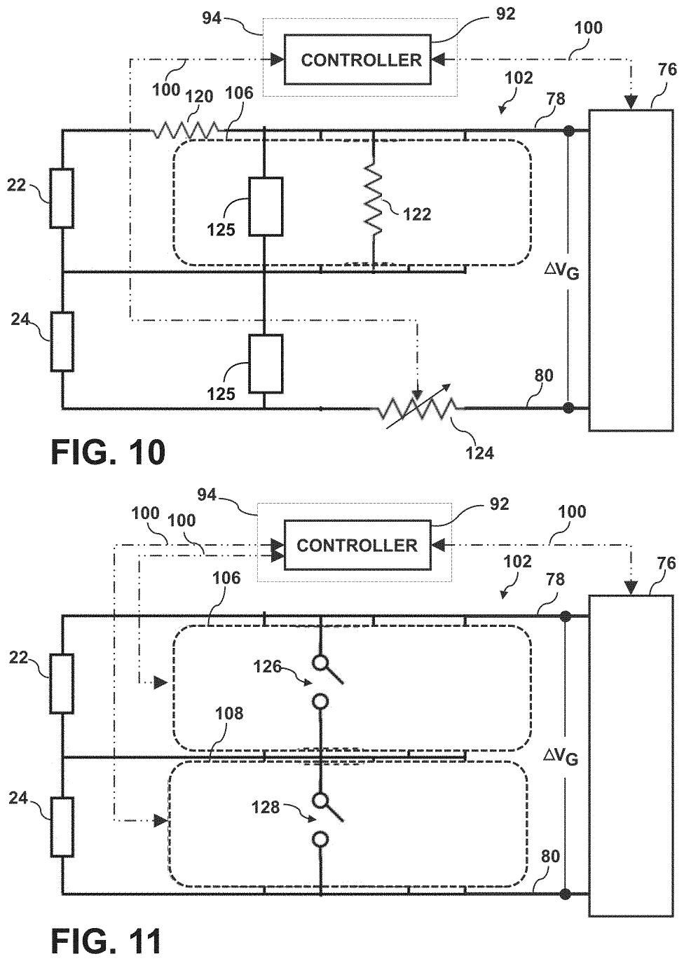

Referring to FIGS. 10 and 11, the electro-optic device 10 may include a first resistor 120 electrically interposing the power supply circuitry 76 and the first electrode 34. A second resistor 122 may electrically interpose the power supply circuitry 76 and the first shared electrode 38 (via, e.g., the first power regulation circuit 106) to regulate voltage across the first electro-optic element 22 and the second electro-optic element 24. It is generally contemplated that any number of electro-optic elements may include any number of corresponding resistors 120, 122 for regulating voltage across the corresponding electro-optic element. According to one aspect of the present disclosure, a variable resistance device 124 may be electrically interposed between the power supply circuitry 76 and either or each of the first electro-optic element 22 and/or the second electro-optic element 24. Because a resistor may interpose each junction of a pair of electrodes and the power supply circuitry 76, the effect may be that as global voltage V_{G} is increased, the electro-optic elements 22, 24 darken in a sequential or cascading manner as the voltage across each electro-optic element 22, 24 passes its threshold voltage. Decreasing the global voltage V_{G} may accomplish the opposite in a clearing cascade fashion. The resistance of the resistors may be similar or different and may be configured to allow a single voltage to cause a ramping effect (e.g., a sequentially delayed voltage response).

With reference to FIG. 10, the variable resistance device 124 may be electrically connected to the second electrode 36. The variable resistance device 124 may be configured to set a specific resistance value during the manufacturing process for the electro-optic device 10. The variable resistance device 124 may, additionally or alternatively, be configured to communicate with the controller 92. The controller 92 may be operable to adjust the resistance of the variable resistance device 124 based on the desired voltage profile of the electro-optic device 10. For example, setting the variable resistance device 124 to a lower resistance may allow for a greater current to flow through the electro-optic elements 22, 24 and/or lower the voltage across at least one electro-optic elements 22, 24. Similarly, the resistances chosen for the first resistor 120 and/or the second resistor 122, (along with an n^{th} resistor corresponding to an n^{th} electro-optic element) may have values for maintaining a desired voltage across each electro-optic element 22, 24. By way of example, a target voltage across each electro-optic element 22, 24 may be 1.2 V and the resistance of each of the first resistor 120 and second resistor 122 may be configured to achieve approximately the target voltage across each electro-optic element 22, 24 at a given current.

With continued reference to FIG. 10, a bypass circuit 125 may be provided in parallel with each electro-optic element 22, 24. For example, the bypass circuit 125 may provide an alternative path for current flowing from element 22 to resistor 122. The bypass circuit 125 may incorporate a diode to limit current through or voltage across element 22 as element 24 is activated. The incorporation of the bypass circuit 125 may limit over-voltage or over-current to the electro-optic device 10.

Referring more specifically to FIG. 11, the power regulation circuitry 102 may include a first switch 126 in parallel with the first electro-optic element 22 and a second switch 128 in parallel with the second electro-optic element 24. The controller 92 may be operable to control the first switch 126 and the second switch 128 in order to control the voltage and/or current flowing through each electro-optic element 22, 24 based on a pre-configured algorithm. The switches 126, 128 may also be controlled based on a voltage across one or more of the electro-optic elements 22, 24 or a current through one or more of the electro-optic elements 22, 24. For example, if a voltage across the first electro-optic element 22 approaches or exceeds a threshold voltage (e.g., 1.2 V), the controller 92 may be operable to close the first switch 126 to divert current away from the first electro-optic element 22. Conversely, if a voltage across the first electro-optic element 22 falls below another threshold voltage (e.g., 0.8 V), the controller 92 may be operable to open the first switch 126 to allow more current to flow through the first electro-optic element 22. This is a non-limiting example and may apply to any electro-optic element having a switch in parallel with that electro-optic element.

It is generally contemplated that one or both switches 126, 128 may be an electrically-actuatable switch, such as a transistor, a plurality of transistors, or any type of switching circuit. Further, one or both switches 126, 128 may be controlled via pulse-width modulation (PWM) and configured to divert an average current through one or both switches 126, 128 based on a duty cycle of a PWM signal. It is generally contemplated that the disclosure is not limited to a specific number of electro-optic elements of the electro-optic device 10. As previously described, the electro-optic device 10 may include n number of electro-optic elements having corresponding power regulation circuitry 102 that is similar to or different than the first power regulation circuit 106 and/or the second power regulation circuit 108.

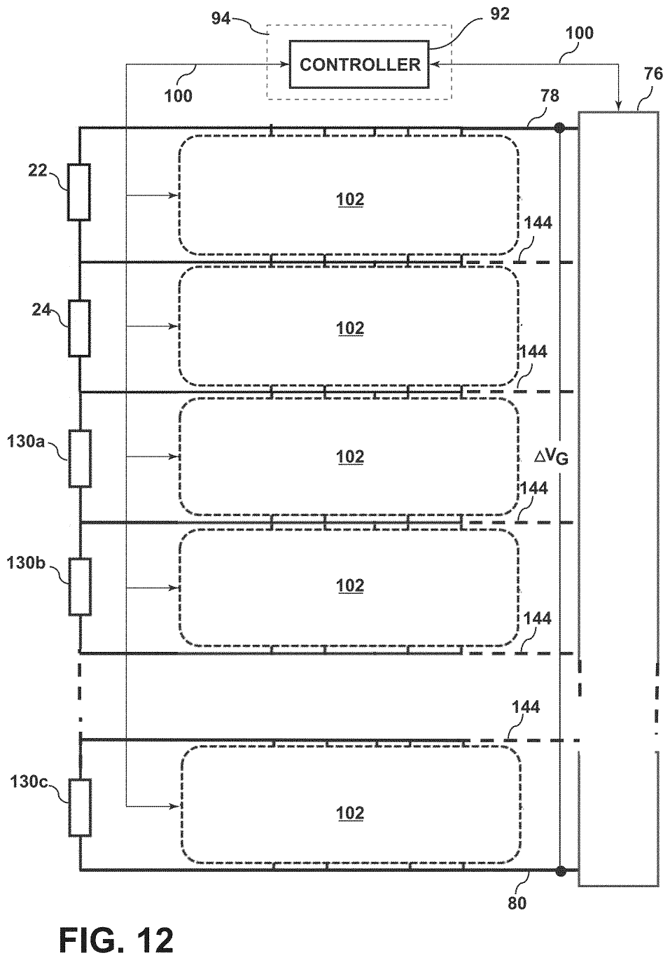

Referring to the FIGS. 12-14 an exemplary electro-optic device 10 incorporating five electro-optic elements is illustrated showing the scalability of the electro-optic device 10 of the present disclosure. For example, the electro-optic device 10 can include a plurality of additional electro-optic elements 130a, 130b, 130c disposed in series with the first electro-optic element 22 and the second electro-optic element 24 previously described. In the aspects illustrated, the plurality of additional electro-optic elements 130a, 130b, 130c may include three additional electro-optic elements, though any number may be contemplated. The exemplary additional electro-optic element 130a, 130b, 130c, may be structured similar to the first and second electro-optic elements 22, 24, having corresponding pairs of electrodes, cavities 134a, 134b, 134c, electro-optic segments 136a, 136b, 136c, gaps 52, etc. Using the first additional electro-optic element 130a as an example, the first additional electro-optic element 130a may include a shared electrode, e.g., second electrode 36, common to the second electro-optic element 24. The shared electrode 38 illustrated in FIGS. 2 and 3, for example, may operate as a first shared electrode 38, and the second electrode 36 may operate as a second shared electrode. The arrangement of sequential, shared electrodes for the remaining additional electro-optic elements (e.g., second and third additional electro-optic elements 130b, 130c) is depicted in FIGS. 13 and 14 and, as previously described, may be applied to any number of additional electro-optic elements of the electro-optic device 10.

The number of shared electrodes may be equal to one less than the number of electro-optic elements 22, 24 of the electro-optic device 10. For instance, as illustrated in FIGS. 12-14, five electro-optic elements 22, 24, 130a, 130b, 130c are provided via employment of 4 shared electrodes 36, 38, 132a, 132b and a pair of end electrodes 34, 132c. Stated differently, the total number of electrodes may be the number of electro-optic elements plus 1 (e.g., 6 electrodes, 5 electro-optic elements). It is generally contemplated that these examples are non-limiting and that no specific ratio of electrodes to electro-optic elements is required according to the present disclosure.

Referring more specifically to FIGS. 13 and 14, the plurality of electro-optic elements 22, 24 may form a linear array along the length L of the electro-optic device 10 and share a common radius of curvature r from a common center of curvature c. The electro-optic device 10 may form a flat or slightly curved shape. According to various aspects of the disclosure, each component of the plurality of electro-optic elements 22, 24 may extend generally coplanar with the components of neighboring electro-optic elements. For example, the plurality of electrodes 34, 36, 38, 132a, 132b, 132c may extend in a common plane. It is generally contemplated that an electro-optic device 10 constructed according to various aspects of the disclosure may be scalable, such that any number of electro-optic elements having corresponding power regulation circuits may be included in a single electro-optic device 10.

The electro-optic device 10 illustrated in FIGS. 12 and 13 may provide for additional connection points 138 to the plurality of electrodes 34, 36, 132a, 132b, 132c. According to various aspects of the present disclosure, the plurality of electrodes 34, 36, 38, 132a, 132b, 132c may have one or more intermediate electrodes (e.g., 36 and 132a) that are “landlocked” from direct electrical connection at the first and second ends 54, 56 of the electro-optic device 10. With reference to FIG. 14, the first and second substrates 26, 28 may define one or more apertures 140 for receiving intermediate electrical connections 142 for providing power to the intermediate electrodes 36, 132a. Additionally, or alternatively, the intermediate electrical connections 142 may be busses and be disposed on one or both of the first and second edges 58, 60 of the landlocked electro-optic elements (FIG. 13). Intermediate electrodes or busses may also be disposed, imbedded and concealed along the barriers 46.

With reference to FIG. 12 specifically, general aspects of the electrical configuration of an electro-optic device 10 having n number of electro-optic elements is illustrated (e.g., any number of electro-optic elements between the elements 130b and 130c). The electrical configuration may include any combination of the previously described circuitry in reference to FIGS. 6-11. More specifically, the electrical configuration shown in FIG. 14 may include power supply circuitry 76 and corresponding parts thereof, power regulation circuitry 102 and corresponding parts thereof, etc. Further, a plurality of nodes 144 (e.g., n nodes) may be provided in an alternative, with each of the plurality of nodes 144 functionally corresponding to the third node 90 illustrated and described in reference to FIGS. 6 and 8, and with each of the plurality of nodes 144 interposing two power supplies.

According to some aspects of the present disclosure, some but not all of the electro-optic elements 22, 24, 130a, 130b, 130c may be subject to individualized control via the power regulation circuitry 102 and/or the control circuitry 94. For example, one or more of the intermediate electrodes 36, 132a may have no direct electrical connection and may have a floating voltage relative to one or more of the plurality of electrodes 34, 38, 132b, 132c. This may result in less direct control over one or more of the intermediate electrodes 36, 132a. By providing a smaller size and/or narrower geometry for the electro-optic elements associated with the floating electrodes, lack of individualized control may still allow these electro-optic elements to stay within a target voltage range. It is also generally contemplated that, for configurations with absent intermediate electrical connections 142, the voltage across one or more of electro-optic elements (e.g., elements 24, 130a, and 130b) may be less than the voltage across electro-optic elements 22 and 130c (e.g., the outer electro-optic elements). For example, if one or more of the intermediate electrodes 36, 132a have a greater area or volume than electrodes 34 and 132c, then there may be a lesser overall impedance associated with the intermediate electrodes 36, 132a than electrodes 34, 132c. The lesser overall impedance may result in a lesser voltage (e.g., 0.8 V) across electro-optic elements 22, 130c than electro-optic elements 24, 130a, 130b.

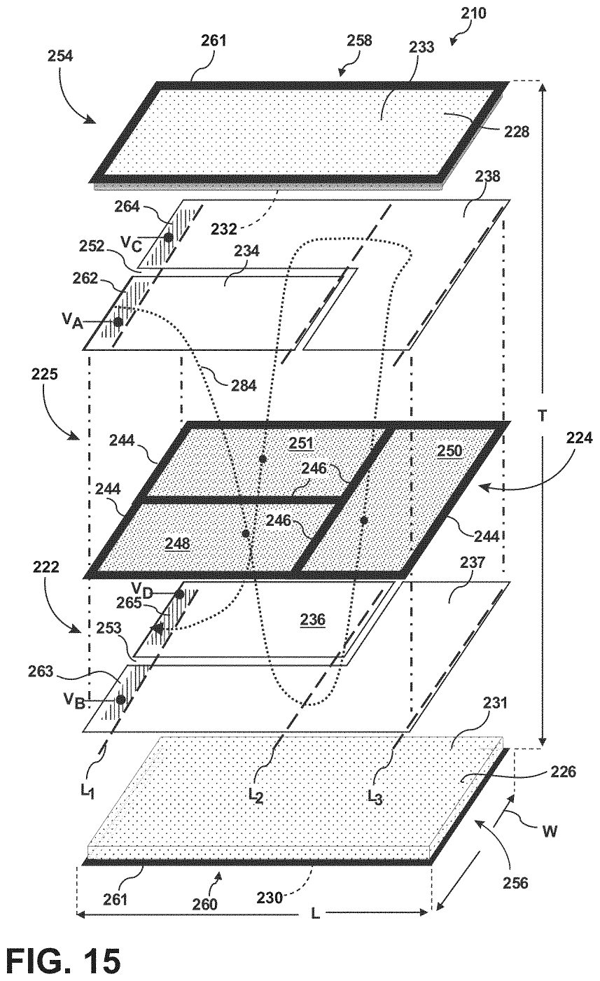

According to one configuration illustrated generally in FIGS. 15-20, an electro-optic device 210 includes a non-linear matrix of electro-optic elements 222, 224, 225 disposed between a first substrate 226 and a second substrate 228. The first substrate 226 has a first surface 230 and a second surface 231 that is opposite the first surface 230. The second substrate 228 has a third surface 232 and a fourth surface 233. The fourth surface 233 is opposite the third surface 232. The second surface 231 faces the third surface 232. In some configurations, the electro-optic elements 222, 224, 225 may have differing geometries. The electro-optic elements 222, 224, 225 may include a first electro-optic element 222 in series with a third electro-optic element 225, with a second electro-optic element 224 interposing the first electro-optic element 222 and the third electro-optic element 225.

The electro-optic device 210 includes first and second end electrodes 234, 236 and first and second shared electrodes 237, 238. The first end electrode 234 and the second shared electrode 238 may be spaced from the second end electrode 236 and the first shared electrode 237 to define at least one cavity (not shown) therebetween. More particularly, the at least one cavity may include a first cavity (not shown) disposed between the first end electrode 234 and a part of the first shared electrode 237, a second cavity disposed between another part of the first shared electrode 237 and a part of the second shared electrode 238, and a third cavity disposed between another part of the second shared electrode 238 and the second end electrode 236. The first cavity, second cavity, and third cavity may be electrically isolated from one another by at least one barrier 244, 246. For example, the at least one barrier may include end barrier 244 disposed about a periphery of the electro-optic device 210 and intermediate barriers 246 dividing a single electro-optic element into a plurality of electro-optic segments 248, 250, 251 that correspond to the first, second, and third cavities. The intermediate barriers 246 may form a T-shape to correspond with the configuration of the electro-optic elements 222, 224, 225. The intermediate barriers 246 between the cavities may serve to physically isolate the first electro-optic segment 248 from the second electro-optic segment 250 and a third electro-optic segment 251.

As described in reference to previous configurations of the electro-optic device 10, the barriers 244, 246 may be formed of an epoxy resin and may be electrically nonconductive. Similarly, the electrodes 234, 236, 237, 238 may include a substantially transparent material that is electrically conductive, such as indium tin oxide (ITO). The electrodes 234, 236, 237, 238 may be surface mounted to the inner surfaces of the first and second substrates 226, 228 (e.g., second and third surfaces 231, 232). Though ITO is discussed, various transparent, electrically conductive materials may be employed with the electrodes 234, 236, 237, 238. The electro-optic segment 248, 250, 251 may include an electrochromic substance that may alter in color when an electrical potential is applied across the electro-optic segment 248, 250, 251.

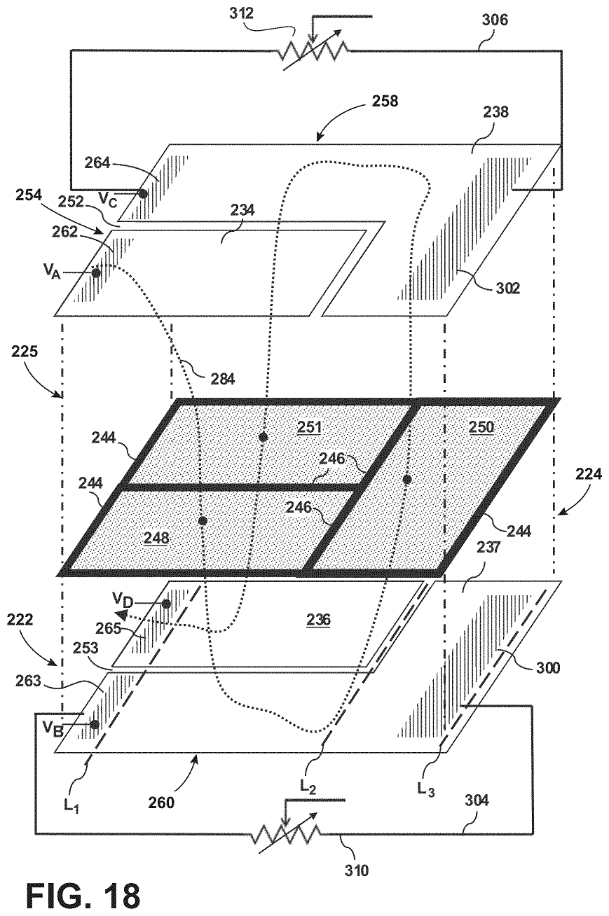

With reference to the structural arrangements illustrated in FIGS. 15 and 18, the first end electrode 234 may be spaced laterally from the second shared electrode 238 to define a first gap 252 therebetween. The second end electrode 236 may be spaced from the first shared electrode 237 to define a second gap 253 therebetween. The gaps 252, 253 may serve to electrically isolate the electrodes 234, 236, 237, 238 and may correspond to the location of the intermediate barrier 246. The first electro-optic element 222 may be formed from the first end electrode 234, the first electro-optic segment 248, and the first shared electrode 237. The second electro-optic element 224 may be formed from the first shared electrode 237, the second electro-optic segment 250, and the second shared electrode 238. The third electro-optic segment 251 may be formed from the second shared electrode 238, the third electro-optic segment 251, and the second end electrode 236.

The electro-optic device 210 may have a length L extending between a first end 254 and a second end 256, opposite the first end 254 of the electro-optic device 210. The electro-optic device 210 can include first and second edges 258, 260 extending between the first end 254 and the second end 256 to form a generally planar shape of the electro-optic device 210. The first end 254 and the second end 256 may be concealed along a top portion or a bottom portion of the electro-optic device 210 via an opaque strip 261 outlining at least a portion of the perimeter of the electro-optic device 210. For example, if the electro-optic device 210 is a sunroof window, then the first end 254 and the second end 256 may be hidden within the perimeter of the sunroof window. At least one electrical conductor 262, 263, 264, 265 (e.g., at least one bus bar) may couple to the at least one electrode 234, 236, 237, 238 adjacent the perimeter and also be concealed via the strip 261. For example, a first electrical conductor 262 may couple to the first end electrode 234 at the first end 254. A second electrical conductor 263 may couple to the first shared electrode 237 at the first end 254. A third electrical conductor 264 may couple to the second shared electrode 238 at the first end 254. A fourth electrical conductor 265 may couple to the second end electrode 236 at the first end 254.

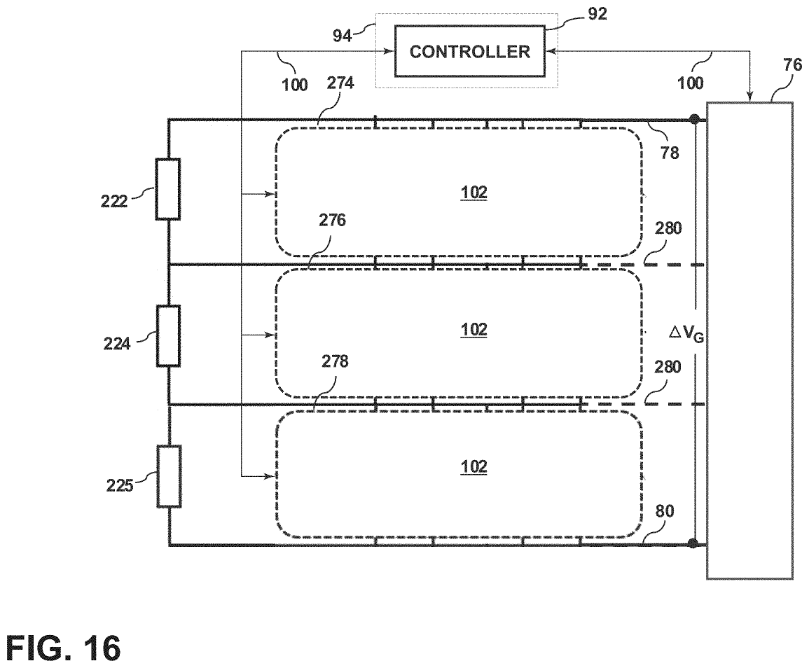

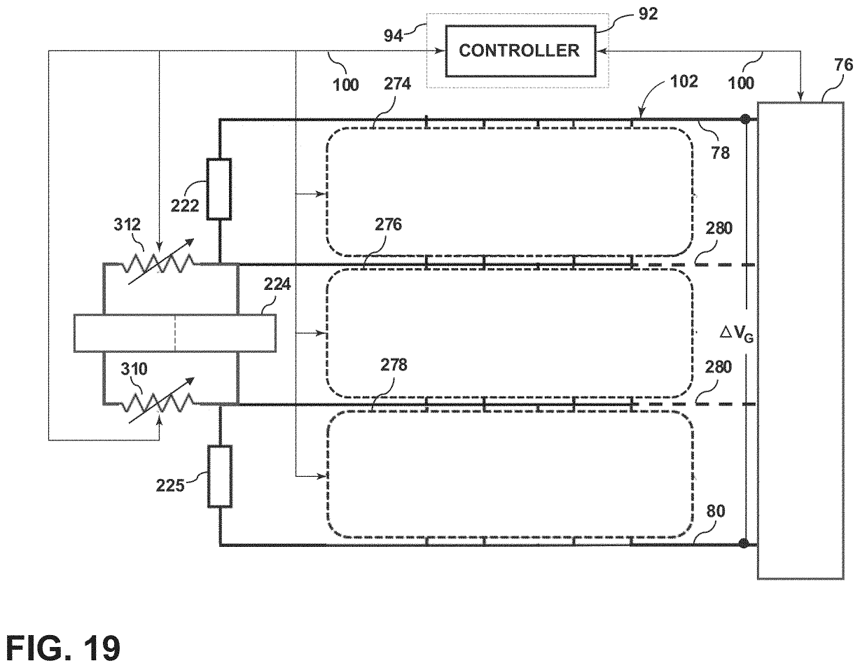

Referring now to FIGS. 16 and 19, the first electro-optic element 222 may be in series with the third electro-optic element 225 via the second electro-optic element 224. Similar to previously described electrical arrangements, the electro-optic device 210 may include the power supply circuitry 76, the power regulation circuitry 102, and the controller 92. The power supply circuitry 76 and power regulation circuitry 102 may have one or more features previously described, including one or more power supplies for supplying the global voltage V_{G} and one or more resistors, switching circuits, capacitors, inductors, variable resistance device 124, etc. in parallel with one or more of the electro-optic elements 222, 224, 225. The power regulation circuitry 102 may include first, second, and third power regulation circuits 274, 276, 278 corresponding to the first, second, and third electro-optic elements 222, 224, 225, respectively. More specifically, the first power regulation circuit 274 may be in parallel with the first electro-optic element 222, the second power regulation circuit 276 may be in parallel with the second electro-optic element 224, and the third power regulation circuit 278 may be in parallel with the third electro-optic element 225. As shown in the alternative, a plurality of nodes 280 may be provided, with each of the plurality of nodes 280 functionally corresponding to the third node 90 illustrated and described in reference to FIGS. 6 and 8 (e.g., with each of the plurality of nodes 280 interposing two power supplies). It will be appreciated from the present disclosure that any number of resistance devices, including the variable resistance device 124, may be disposed on the first node 78, the second node 80, or any of the plurality of nodes 280.

Referring again to the structural depictions of the electro-optic device 210 in FIGS. 15 and 18, the electro-optic device 210 may be configured with particular electrical properties that manifest when the electrical power supply circuitry 76 is applied to the electro-optic device 210. For example, when an electrical potential is applied across the first end electrode 234 and the second end electrode 236, a voltage distribution may be formed across the electro-optic device 210, and an electrical current may flow through the electro-optic device 210. The electrical current may be configured to flow along an electrical current path 284, from the first end electrode 234, through the first electro-optic segment 248, to the first shared electrode 237, through the second electro-optic segment 250, to the second shared electrode 238, through the third electro-optic segment 251, and to the second end electrode 236. The electro-optic segments 248, 250, 251 may have differing geometries and/or orientations. As exemplarily illustrated, the first electro-optic segment 248 and the third electro-optic segment 251 may be disposed adjacent the first end 254 of the electro-optic device 210 and the second electro-optic segment 250 may be disposed at the second end 256 of the electro-optic device 210.

The electrical current path 284 may have a corkscrew shape between the first electro-optic element 222 and the third electro-optic element 225, as illustrated in FIGS. 15 and 18. This may be accomplished by configuring the electro-optic device 210 to direct current lengthwise from the first end 254 to the second end 256, then width-wise from the first edge 258 to the second edge 260, then back from the second end 256 toward the first end 254. It should be appreciated that the electrical current path 284 may correspond to a region of highest current density and may form a plurality of shapes depending on various aspects of the electro-optic device 210. For example, light and/or heat transferred to the electro-optic element 222, 224, 225 may cause current density to shift in various magnitudes and/or directions across the device 210. Further, one or more parts of the electrical current path 284 may deviate from the illustrated path under normal operating conditions. The electro-optic device 210 may be configured to direct current to opposing or adjacent sides of the electro-optic device 210 and that the illustrated configuration of the electrical current path 284 is not limiting.

As illustrated in FIGS. 15 and 18, the electrical current path 284 may extend between the first end electrode 234 and the first shared electrode 237 in a sinusoidal fashion along a length L of the electro-optic device 210 and between a thickness T of the electro-optic device 210. The electrical current path 284 may then extend between the first shared electrode 237 and the second shared electrode 238 through the thickness T of the electro-optic device 210 and along a width W of the electro-optic device 210 in a curved manner. The electrical current path 284 may then be configured to extend between the first shared electrode 237 and the second end electrode 236 across the thickness T of the electro-optic element 222, 224, 225 and in a lengthwise direction along the electro-optic device 210. In this way, electrical current may flow from the first end 254 of the electro-optic device 210 and return to the first end 254 of the electro-optic device 210.

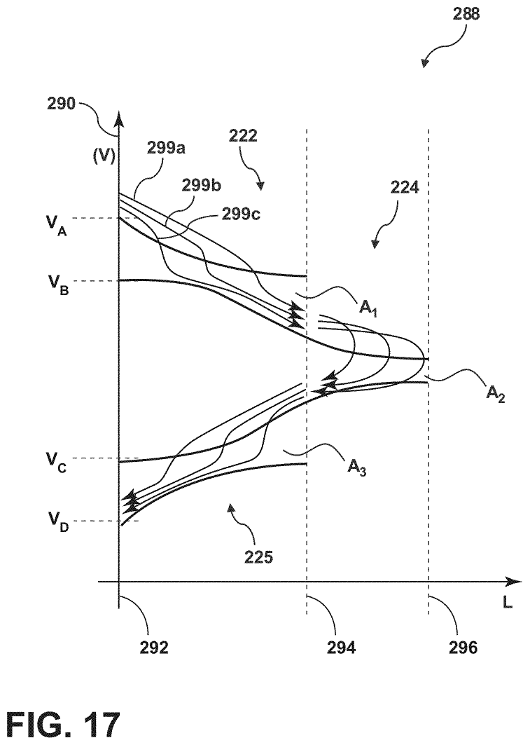

Referring to FIG. 17, a first plot 288 illustrates an exemplary electrical potential distribution 290 along the length L of the electro-optic device 210. More specifically, the first plot 288 illustrates a voltage drop between one or more planes that are generally parallel to the width W of the electro-optic device 210. With reference to FIGS. 15-18, a first segment 292 may correspond to a first width-wise plane intersecting the electro-optic device 210 at a first dashed line L₁ adjacent the first end 254. A second segment 294 may correspond to a second width-wise plane intersecting the electro-optic device 210 at a second dashed line L₂ in an intermediate portion of the electro-optic device 210. A third segment 296 may correspond to a third width-wise plane intersecting the electro-optic device 210 at a third dashed line L₃ adjacent a second end 256 of the electro-optic device 210.

Relative to the second node 80, a plurality of voltages V_{A}, V_{B}, V_{C}, V_{D} may be generated at points proximate to the first end 254 of the electro-optic device 210. For example, the first voltage V_{A} may be generated on the first end electrode 234, the second voltage V_{B} may be generated on the first shared electrode 237, the third voltage V_{C} may be generated on the second shared electrode 238, and the fourth voltage V_{D} may be generated on the second end electrode 236. Intermediate voltages may also be generated along the second and third segments 294, 296. As illustrated in the first plot 288 shown in FIG. 17, an area A₁ bounded between the first voltage V_{A} and the second voltage V_{B} generally demonstrates that an electrical potential (e.g., a delta potential) may exist along the length of the first electro-optic element 222. Similarly, an area A2 bounded between the second voltage V_{B} and the third voltage V_{C} generally demonstrates that an electrical potential may exist along the entire length L of the second electro-optic element 224. Further, an area A₃ bounded between the third voltage V_{C} and the fourth voltage V_{D} generally demonstrates that an electrical potential may exist along the length L of the third electro-optic element 225.

The electrical potential across any two points on a width-wise plane intersecting one of the electro-optic elements 222, 224, 225 may not match all pairs of similarly-situated points. This is generally illustrated in the first plot 288 via a varying height of each bounded area A₁, A₂, A₃. The first plot 288 also includes three exemplary electrical currents 299a, 299b, 299c flowing through the electro-optic device 210. Because the potential may vary along the length of the electro-optic element 222, 224, 225, as illustrated, the current density may also vary along the length of the electro-optic element 222, 224, 225, thereby forming the electrical current path 284 generally illustrated in FIG. 15.

Referring more particularly to FIGS. 18-20, auxiliary electrical conductors 300, 302 may be coupled to the second end 256 of the electro-optic elements 222, 224, 225 on one or both of the first shared electrode 237 and the second shared electrode 238 to draw current density toward the second end 256. For example, a first auxiliary electrical conductor 300 may be disposed on the first shared electrode 237. The auxiliary electrical conductors 300, 302 may be bus bars similar to the preceding examples. With reference to FIGS. 18 and 19 in particular, first auxiliary circuit 304 may be operable to interpose the first auxiliary electrical conductor 300 and the second electrical conductor 263. A second auxiliary electrical conductor 302 may be disposed on the second shared electrode 238, and a first auxiliary circuit 304 may be operable to interpose the second auxiliary electrical conductor 302 and the third electrical conductor 264. One or both of the first and second auxiliary circuits 304, 306 may include a variable resistance device 310, 312. For example, a first variable resistance device 310 may be operable to control an electrical potential across and/or current between the first auxiliary electrical conductor 300 and the second auxiliary electrical conductor 302. A second variable resistance device 312 may be operable to control an electrical potential across and/or current between the second auxiliary electrical conductor 302 and the third electrical conductor 264. The variable resistance devices 310, 312 may be preconfigured for a desired voltage drop, or may be actively controlled via the controller 92. According to some aspects, the voltage drop may be approximately 0 V or an electrical short.

The first and second auxiliary electrical conductors 300, 302 may comprise electrically conductive material, such as copper or tin, and the auxiliary electrical conductors 300, 302 may be disposed along the width, length, or around any part of one or more of the electrodes 234, 236, 237, 238. The auxiliary electrical conductors 300, 302 may also be disposed toward the second end 256. The first and second auxiliary electrical conductors 300, 302 may also be configured to divert current density toward second end 256 of the electro-optic device 210 and/or first and second edges 258, 260 of the electro-optic device 210. For example, the first and second auxiliary electrical conductors 300, 302 may extend at least partially along the first and second edges 258, 260 adjacent the second end 256. The location and presence of the first and second auxiliary electrical conductors 300, 302 may serve to alter the electrical current path 284 as illustrated in FIG. 18.

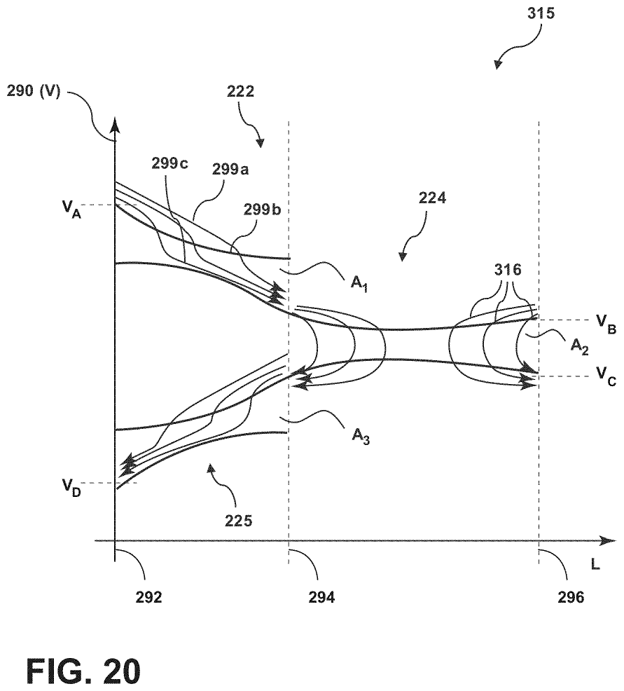

The electrical current path 284 demonstrated in FIG. 18 may have similar properties (e.g., shape, electrical conductivity, resistance, etc.) to the electrical current path 284 illustrated in FIG. 15, but be distributed more peripherally (e.g., closer to the edges 258, 260). As illustrated in a second plot 315 (see FIG. 20), outer currents 316 may be generated adjacent the second end 256 of the electro-optic device 210. Additionally, the area of the auxiliary electrical conductors 300, 302 contacting the shared electrodes 237, 238 may, in some instances, be greater than or lesser than the area of each of the first, second, third, and fourth electrical conductors 262, 263, 264, 265. For example, the materials, proportions, and corresponding conductive capacity/efficiency of each of the electrodes and electrical conductors may be sized to distribute current density throughout the second electro-optic 224, 225 more uniformly and consistent with current density associated with the first and/or third electro-optic cells 222, 225. In some configurations, the area of the auxiliary electrical conductors 300, 302 contacting the shared electrodes 237, 238 is about twice the area of each of the first, second, third, and fourth electrical conductors 262, 263, 264, 265 contacting the electrodes 234, 236, 237, 238.

The electro-optic elements 222, 224, 225 and the first and second substrates 226, 228 may be formed of various materials. For example, the first and second substrates 226, 228 may include plastic materials. Plastic materials for the first and second substrates 226, 228 may include, but are not limited to, a polycarbonate, polyethylene terephthalate (PET), polyethylene naphthalate (PEN), polyesters, polyamides, polyimides, acrylics, cyclic olefins, polyethylene (PE), like metallocene polyethylene (mPE), silicones, urethanes, epoxies, and various polymeric materials. The first and second substrates 226, 228 may also be of various forms of glass, crystals, metals, and/or ceramics, including, but not limited to, soda lime float glass, borosilicate glass, boro-aluminosilicate glass, quartz, or various other compositions. When using glass substrates, the first and second substrates 226, 228 can be annealed, heat strengthened, chemically strengthened, partially tempered, or fully tempered. The electro-optic elements 222, 224, 225 forming the window 14 may be supported by a frame, which may correspond to a partial or full frame that may be used to support a window 14 panel as desired.

The first and second substrates 226, 228, as well as one or more protective layers, may be adhered together by one or more thermoset and/or thermoplastic materials. For example, the thermoset and/or thermoplastic material may correspond to at least one of the following materials: polyvinyl butyral (PVB), ethylene-vinyl acetate (EVA), thermoset EVA ethylene-vinyl acetate (EVA), and thermoplastic polyurethane (TPU). The specific materials are described in the disclosure and may correspond to exemplary materials that may be employed as thermoset and/or thermoplastic materials to adhere to one or more of the first and second substrates 226, 228 and/or additional protective layers or coating. Accordingly, the specific examples described herein are to be considered non-limiting examples. Further, the materials of the electro-optic elements, electrodes, mediums, substrates, and barriers described throughout the disclosure may be present in many or only one of the above configurations illustrated in FIGS. 2, 3, 5, 13-15, and 18. Further, any of the above-described circuitry may be employed in the various electrical approximations shown and described with respect to FIGS. 4, 6-12, 16, and 19.

Referring now to FIG. 21, yet another example of the electro-optic device 10 is shown. Similar to many of the previous examples, the electro-optic device includes a plurality of electro-optic elements 22, 24 disposed between a first substrate 26 and a second substrate 28. As shown, the first electro-optic element 22 is adjacent to the second electro-optic element 24 having a common perimeter edge or boundary. In this configuration, the electro-optic element 24 may form adjacent segments 48, 50 of a continuous panel formed between the substrates 26, 28 of the electro-optic device 10. As provided by various configurations of the electro-optic device 10, the disclosure may provide for improved response times when transitioning from darkened or opaque states to clear or transparent states and vice versa by controlling the control signals communicated to each of a plurality of corresponding electrodes 320a, 320b, 320c, 320d.

The example shown in FIG. 21 may be representative of an electro-optic device 10 having an operation that may maintain a transmission state for extended durations without continuously controlling a voltage potential across opposing electrodes 322. For example, the opposing electrodes may comprise first opposing electrodes 320a, 320b and second opposing electrodes 320c, 320d. In operation, the structure and corresponding state control of the corresponding segments 48, 50 of the device 10 may be provided by incorporating an electro-chromic technology that includes surface confined materials forming anodic elements 324a, 324b or layers and cathodic element 326a, 326b or layers on interior surfaces of the opposing electrodes 322. For example, the first electro-optic element 22 may comprise a first anodic element 324a disposed on the first electrode 320a and a first cathodic element 326a disposed on the second electrode 320b. Similarly, the second electro-optic element 24 may comprise a second anodic element 324b disposed on the third electrode 320c and a second cathodic element 326b disposed on the fourth electrode 320d. Additionally, two of the electrodes 320b, 320c, which may be disposed on opposing substrates 26, 28, may be conductively connected via a conducting member 328 that may form a common node 330 or common conductive element comprising the second electrode 320b and the third conductive electrode 320c conductively connected via the conducting member 328. In this configuration, the adjacent segments 48, 50 may be connected in series having common or similar control signals applied via the electrodes 320b, 320c forming the common node 330.

As demonstrated, the anodic elements 324a, 324b may be separated by an ionically conductive electrolyte 332 disposed within the cavities 40, 42 formed by the corresponding electro-optic elements 22, 24. In some cases, the cavities 40, 42 may be separated by an insulating barrier 334 conductively isolating the electrolyte 332. As shown, the conducting member 328 may correspond to a conductive bead, filament, jumper, or similar conductive connection that may be enclosed within the material forming the insulating barrier 334. In such configurations, the signals and corresponding electrical response of the first electrode 320a and the fourth electrode 320d may be insulated or isolated by the insulating barrier 334 while the second electrode 320b may be conductively connected to the third conductive electrode 320c forming the common node 330. Though the insulating barrier 334 is described and shown in the exemplary embodiment, it may be useful in some cases to omit the insulting barrier 334 and rely on the electrolyte 332 to effectively isolate the first electrode 320a from the fourth electrode 320d. Such a configuration may be beneficial in some cases depending on the desired operation of the device 10.

As discussed in reference to FIG. 21, the device 10 may be operable to maintain a darkened or low-transmission state at open circuit. The anodic elements 324a, 324b or layers and the cathodic elements 326a, 326b or layers may be separated by the electrolyte 332 in the form of colorless, or at least nearly colorless, transparent and chemically stable element. Such an electrolyte may allow for the free diffusion of ions through the electrolyte 330 but prohibit (or at least significantly impede) the free passage of electrons or electronic current. Thus, where the device 10 is in an electrochemically active and/or darkened state, passage of ions is allowed through electrolyte 330 while impeding the passage of electrons. The electrolyte 330 may also be a membrane, or more specifically an ion exchange membrane. For example, if the electrolyte 332 is a cationic membrane, it will allow for passage of cations while excluding anions, and vice versa.

In various implementations, the anodic and cathodic materials forming the anodic elements 324 and the cathodic elements 326 or layers may be in a solution phase, a gel phase, retained within the chambers, or confined to the interior surfaces by coating and in some cases crosslinking onto the electrodes 320a, 320b, 320c, 320d. In various examples, the anodic materials may include, but are not limited to, metallocenes, 5,10-dihydrophenazines, phenothiazines, phenoxazines, carbazoles, triphendioxazines, triphenodithiazines and related compounds. The cathodic material may be a viologen, a low-dimerizing viologen, a non-dimerizing viologen, or metal oxides such as tungsten oxides as those terms are used in the art. The term low-dimerizing viologen is applied to some viologens that show dimerization characteristics to a lesser extent than dimerizing viologens. Illustrative viologens include, but are not limited to, methyl viologen, octyl viologen, benzyl viologen, and polymeric viologens. In addition, further viologens are described in U.S. Pat. Nos. 4,902,108; 6,188,505; 5,998,617; 6,710,906; and in U.S. Patent Application Publication. No. 2015/0346573. In addition, further descriptions of confined anodic element 324 and confined cathodic element 326 are in U.S. Pat. No. 10,481,456 and in U.S. Patent Application Publication No. 2020/0409225.

With reference to any of the above aspects of the electro-optic device according to the present disclosure (e.g., electro-optic device 10 and or electro-optic device 210), in operation, the arrangement of the electro-optic elements in series may prevent the need for additional conductive materials (e.g., wires and busbars) and improve structural uniformity and responsiveness to electric stimuli. Serializing the electro-optic elements may provide a simpler manufacturing process for the electro-optic device. One potential issue with serializing the electro-optic elements is overvoltage of any individual electro-optic element. Certain types of electro-optic cells, such as electrochromic cells, may be damaged if subject to prolonged overvoltage. Therefore, monitoring the electrical impedance, voltage, and/or current across each of the electro-optic elements may allow the electro-optic device to ensure overvoltage is prevented and/or exposure time is limited. In this way, the lifetime of the electro-optic elements may be extended and uniform, such that certain electro-optic elements are not subject to consistent overvoltage operation while other electro-optic elements of the electro-optic device are within a safe voltage threshold. The electrical impedance may be subject to change based on environmental factors, such as heat (e.g., from sunlight) and the spacing, size, and geometry of the electro-optic elements, including the electrodes. By monitoring and controlling the impedance, voltage, and/or current of each electro-optic element, the voltage across each electro-optic element may be effectively regulated.

The power supply circuitry, the power regulation circuitry, and the control circuitry disclosed herein may operate together to maintain a target voltage (e.g., <0.9 V, <1.0 V, <1.1 V, <1.2 V per electro-optic element, or any other target voltage) and/or current across the electro-optic elements. For example, a single variable-voltage power supply may provide a global voltage across the entire array of electro-optic elements. Blow-off or bypass valves (e.g., a pair of opposing diodes), switching circuitry, gate circuitry, shunt resistors, and the like may be implemented in parallel with each electro-optic element in order to divert current from or regulate voltage across each electro-optic cell. Additionally, or alternatively, a controller may be operable to control an output of the variable-voltage power supply based on monitored properties of the power regulation circuitry and/or the electro-optic elements. The power regulation circuitry and/or the power supply circuitry may be operated via electrical hardware only (i.e., lacking software algorithms). As an alternative to the single variable-voltage power supply, a plurality of power supplies may be provided in parallel, with one of the plurality of power supplies corresponding with each electro-optic element in a stacked configuration (e.g., the power supplies in series and the electro-optic elements in series with a common node of a pair of electro-optic element electrically connecting with a common node of a pair of power supplies). The power supplies may employ forward-bias powering, reverse biasing, and/or voltage modulation for each electro-optic element or a select number of electro-optic elements.

In general, according to various aspects of the disclosure, the arrangement and electrical control of the electro-optic elements may allow deviation in size and/or geometry of the electro-optic elements. More specifically, overvoltage/over-current arising from size or spacing variance in the electro-optic elements, as well as changes in resistance/impedance due to temperature fluctuations, may be prevented according to various aspects of the present disclosure, including more individualized control of the electro-optic elements.

According to various aspects, the electro-optic element may include memory chemistry configured to retain a state of transmittance when the vehicle and the window control module are inactive (e.g., not actively supplied energy from a power supply of the vehicle). That is, the electro-optic element may be implemented as an electrochromic device having a persistent color memory configured to provide a current during clearing for a substantial time period after being charged. An example of such a device is discussed in U.S. Pat. No. 9,964,828 entitled “ELECTROCHEMICAL ENERGY STORAGE DEVICES,” the disclosure of which is incorporated herein by reference in its entirety.

The electro-optic element may correspond to an electrochromic device being configured to vary the transmittance of the window discussed herein in response to an applied voltage from the window. Examples of control circuits and related devices that may be configured to provide for electrodes and hardware configured to control the electro-optic element are generally described in commonly assigned U.S. Pat. No. 8,547,624 entitled “VARIABLE TRANSMISSION WINDOW SYSTEM,” U.S. Pat. No. 6,407,847 entitled “ELECTROCHROMIC MEDIUM HAVING A COLOR STABILITY,” U.S. Pat. No. 6,239,898 entitled “ELECTROCHROMIC STRUCTURES,” U.S. Pat. No. 6,597,489 entitled “ELECTRODE DESIGN FOR ELECTROCHROMIC DEVICES,” and U.S. Pat. No. 5,805,330 entitled “ELECTRO-OPTIC WINDOW INCORPORATING A DISCRETE PHOTOVOLTAIC DEVICE,” the entire disclosures of each of which are incorporated herein by reference.

Examples of electrochromic devices that may be used in windows are described in U.S. Pat. No. 6,433,914 entitled “COLOR-STABILIZED ELECTROCHROMIC DEVICES,” U.S. Pat. No. 6,137,620 entitled “ELECTROCHROMIC MEDIA WITH CONCENTRATION-ENHANCED STABILITY, PROCESS FOR THE PREPARATION THEREOF AND USE IN ELECTROCHROMIC DEVICES,” U.S. Pat. No. 5,940,201 entitled “ELECTROCHROMIC MIRROR WITH TWO THIN GLASS ELEMENTS AND A GELLED ELECTROCHROMIC MEDIUM,” and U.S. Pat. No. 7,372,611 entitled “VEHICULAR REARVIEW MIRROR ELEMENTS AND ASSEMBLIES INCORPORATING THESE ELEMENTS,” the entire disclosures of each of which are incorporated herein by reference. Other examples of variable transmission windows and systems for controlling them are disclosed in commonly assigned U.S. Pat. No. 7,085,609, entitled “VARIABLE TRANSMISSION WINDOW CONSTRUCTIONS,” and U.S. Pat. No. 6,567,708 entitled “SYSTEM TO INTERCONNECT, LINK, AND CONTROL VARIABLE TRANSMISSION WINDOWS AND VARIABLE TRANSMISSION WINDOW CONSTRUCTIONS,” each of which is incorporated herein by reference in its entirety. In other embodiments, the electro-optic device may include a suspended particle device, liquid crystal, or other system that changes transmittance with the application of an electrical property.

According to some aspects of the disclosure, an electro-optic device comprises a first electro-optic element and a second electro-optic element in series with the first electro-optic element via a common node conductively connecting the first electro-optic element to the second electro-optic element. A power supply circuitry includes a first node and a second node, wherein the first node connects the power supply circuitry to the first electro-optic element, and wherein the second node connects the power supply circuitry to the second electro-optic element.

According to various aspects, the disclosure may implement one or more of the following features or configurations in various combinations:
the common node comprises a first shared electrode common to the first electro-optic element and the second electro-optic element;
the power supply circuitry includes a first power supply and a second power supply in series with the first power supply via a third node connecting to the first shared electrode;
a controller operable to control the first power supply and the second power supply;
power regulation circuitry interposed between the first shared electrode and one of the first node and the second node;
a controller operable to control the power regulation circuitry based on an electrical potential of the first shared electrode;
control circuitry operable to monitor an electrical potential of the first shared electrode relative to one of the first node and the second node and control the power supply circuitry based on the electrical potential;
a third electro-optic element in series with the second electro-optic element via a second shared electrode common to the second electro-optic element and the third electro-optic element;
the first electro-optic element and the second electro-optic element are electrochromic cells;
the common node comprises a plurality of electrodes interconnected via a conductive element;
an insulating barrier disposed between the first electro-optic element and the second electro-optic element, wherein the conductive element extends through the insulating layer conductively connecting the first electro-optic element to the second electro-optic element;
the common node is formed by a first electrode of the first electro-optic element and a second electrode of the electro-optic element conductive connected via the conductive element; and/or
an electrolyte disposed between the first electrode and the second electrode, wherein the conductive element conductively connects the first electrode to the second electrode across the electrolyte.

According to other aspects of the disclosure, a method for controlling an electro-optic device comprises a plurality of electro-optic elements connected in series. The method includes controlling a first transmittance of a first electro-optic element by selectively generating a first electrical potential difference between a first electrode and a second electrode across the first electro-optic element of the plurality of electro-optic elements, and controlling a second transmittance of a second electro-optic element by selectively generating a second electrical potential difference between the second electrode and a third electrode across the second electro-optic element of the plurality of electro-optic elements, wherein the second electrode comprises a node between the first electro-optic element and the second electro-optic element.

According to various aspects, the disclosure may implement one or more of the following features or configurations in various combinations:
monitoring an intermediate voltage of the least one of the first electrical potential difference or the second electrical potential difference relative to the second electrode, and controlling at least one of the first electrical potential difference and the second electrical potential difference in response to the intermediate voltage; and/or
independently controlling the first transmittance via the first electrical potential difference and the second transmittance via the second electrical potential difference in response to the intermediate voltage.

According to another aspect of the disclosure, an electro-optic device comprises a first electro-optic element including a first electrode spaced from a least one second electrode defining a first cavity therebetween, the first cavity comprising a first electro-optic medium and a second electro-optic element connected in series with the first electro-optic element via the at least one second electrode, the second electro-optic element including a third electrode spaced from the at least one second electrode defining a second cavity therebetween, the second cavity comprising a second electro-optic medium. The at least one second electrode is conductively connected between the first electrode and the second electrode and forms a common node between the first electro-optic element and the second electro-optic element.

According to various aspects, the disclosure may implement one or more of the following features or configurations in various combinations:
an electrically insulating barrier disposed between the first cavity and the second cavity, wherein the insulating barrier electrically insulates the first electro-optic medium from the second electro-optic medium and the series connection provided by the least one second electrode provides for the series connection across the electrically insulating barrier;
at least one second electrode forms a first opposing electrode opposite the first electrode across the first cavity and a second opposing electrode opposite the second electrode across the second cavity, wherein the first opposing electrode and the second opposing electrode are conductively connected via a conductive element thereby forming the series connection; and/or
at least one second electrode is a continuous electrode formed on a substrate of the electro-optic device, wherein the second electrode is common to the first electro-optic element and the second electro-optic element, and wherein, when an electric potential is applied across the first electrode and the third electrode, an electrical current is configured to flow in an electrical current path from the first electro-optic medium to the second electro-optic medium via the second electrode.

It will be understood that any described processes or steps within described processes may be combined with other disclosed processes or steps to form structures within the scope of the present device. The exemplary structures and processes disclosed herein are for illustrative purposes and are not to be construed as limiting.

It is also to be understood that variations and modifications can be made on the aforementioned structures and methods without departing from the concepts of the present device, and further it is to be understood that such concepts are intended to be covered by the following claims unless these claims by their language expressly state otherwise.

The above description is considered that of the illustrated embodiments only. Modifications of the device will occur to those skilled in the art and to those who make or use the device. Therefore, it is understood that the embodiments shown in the drawings and described above are merely for illustrative purposes and not intended to limit the scope of the device, which is defined by the following claims as interpreted according to the principles of patent law, including the Doctrine of Equivalents.

What is claimed is:

1. An electro-optic device comprising:
a first electro-optic element;
a second electro-optic element in series with the first electro-optic element via a common node conductively connecting the first electro-optic element to the second electro-optic element; and
power supply circuitry including a first node and a second node, wherein the first node connects the power supply circuitry to the first electro-optic element, and wherein the second node connects the power supply circuitry to the second electro-optic element.

2. The electro-optic device of claim 1, wherein the common node comprises a first shared electrode common to the first electro-optic element and the second electro-optic element.

3. The electro-optic device of claim 2, wherein the power supply circuitry includes a first power supply and a second power supply in series with the first power supply via a third node connecting to the first shared electrode.

4. The electro-optic device of claim 3, further comprising:
a controller operable to control the first power supply and the second power supply.

5. The electro-optic device of claim 2, further comprising:
power regulation circuitry interposed between the first shared electrode and one of the first node and the second node.

6. The electro-optic device of claim 5, further comprising:
a controller operable to control the power regulation circuitry based on an electrical potential of the first shared electrode.

7. The electro-optic device of claim 2, further including control circuitry operable to:
monitor an electrical potential of the first shared electrode relative to one of the first node and the second node; and
control the power supply circuitry based on the electrical potential.

8. The electro-optic device of claim 2, further comprising:
a third electro-optic element in series with the second electro-optic element via a second shared electrode common to the second electro-optic element and the third electro-optic element.

9. The electro-optic device of claim 1, wherein the first electro-optic element and the second electro-optic element are electrochromic cells.

10. The electro-optic device of claim 1, wherein the common node comprises a plurality of electrodes interconnected via a conductive element.

11. The electro-optic device of claim 10, further comprising:
an insulating barrier disposed between the first electro-optic element and the second electro-optic element, wherein the conductive element extends through the insulating layer conductively connecting the first electro-optic element to the second electro-optic element.

12. The electro-optic device of claim 10, wherein the common node is formed by a first electrode of the first electro-optic element and a second electrode of the electro-optic element conductive connected via the conductive element.

13. The electro-optic device of claim 10, further comprising:
an electrolyte disposed between the first electrode and the second electrode, wherein the conductive element conductively connects the first electrode to the second electrode across the electrolyte.

14. A method for controlling an electro-optic device comprising a plurality of electro-optic elements connected in series, the method comprising:
controlling a first transmittance of a first electro-optic element by selectively generating a first electrical potential difference between a first electrode and a second electrode across the first electro-optic element of the plurality of electro-optic elements; and
controlling a second transmittance of a second electro-optic element by selectively generating a second electrical potential difference between the second electrode and a third electrode across the second electro-optic element of the plurality of electro-optic elements, wherein the second electrode comprises a node between the first electro-optic element and the second electro-optic element.

15. The method according to claim 14, further comprising:
monitoring an intermediate voltage of the least one of the first electrical potential difference or the second electrical potential difference relative to the second electrode; and
controlling at least one of the first electrical potential difference and the second electrical potential difference in response to the intermediate voltage.

16. The method according to claim 15, further comprising:
independently controlling the first transmittance via the first electrical potential difference and the second transmittance via the second electrical potential difference in response to the intermediate voltage.

17. An electro-optic device comprising:
a first electro-optic element including a first electrode spaced from a least one second electrode defining a first cavity therebetween, the first cavity comprising a first electro-optic medium;
a second electro-optic element connected in series with the first electro-optic element via the at least one second electrode, the second electro-optic element including a third electrode spaced from the at least one second electrode defining a second cavity therebetween, the second cavity comprising a second electro-optic medium; and
wherein the at least one second electrode is conductively connected between the first electrode and the second electrode and forms a common node between the first electro-optic element and the second electro-optic element.

18. The electro-optic device according to claim 17, further comprising:
an electrically insulating barrier disposed between the first cavity and the second cavity, wherein the insulating barrier electrically insulates the first electro-optic medium from the second electro-optic medium and the series connection provided by the least one second electrode provides for the series connection across the electrically insulating barrier.

19. The electro-optic device according to claim 17, wherein the at least one second electrode forms a first opposing electrode opposite the first electrode across the first cavity and a second opposing electrode opposite the second electrode across the second cavity, wherein the first opposing electrode and the second opposing electrode are conductively connected via a conductive element thereby forming the series connection.

20. The electro-optic device according to claim 17, wherein the at least one second electrode is a continuous electrode formed on a substrate of the electro-optic device, wherein the second electrode is common to the first electro-optic element and the second electro-optic element, and wherein, when an electric potential is applied across the first electrode and the third electrode, an electrical current is configured to flow in an electrical current path from the first electro-optic medium to the second electro-optic medium via the at least one second electrode.
